(19) United States
(12) Patent Application Publication
(10) Pub. No.: US 2025/0107169 A1
(43) Pub. Date: Mar. 27, 2025

(54) PROTECTION OF MESA EDGES IN SEMICONDUCTOR DEVICES

(71) Applicant: Woflspeed, Inc., Durham, NC (US)

(72) Inventors: Madankumar Sampath, Durham, NC (US); Rahul R. Potera, Apex, NC (US)

(21) Appl. No.: 18/370,995

(22) Filed: Sep. 21, 2023

(51) Int. Cl. H01L 29/06; H01L 21/311

(52) U.S. Cl. CPC H10D 62/113; H01L 21/31144

(57) ABSTRACT

A method of forming a semiconductor device includes forming mesa stripe structure on a semiconductor substrate, the mesa stripe structure including a plurality of alternating trenches and mesa stripes, forming a dielectric spacer on the mesa stripe structure, and forming an etch mask on a portion of the mesa stripe structure. The etch mask covers at least a portion of a first mesa stripe of the plurality of mesa stripes. The dielectric spacer is etched to expose surfaces of the mesa stripes other than the portion of the first mesa stripe that is covered by the etch mask. The etch mask is removed, and a metal layer is formed on the mesa stripe structure. The metal layer forms metal contacts to the exposed surfaces of the mesa stripes. Related semiconductor devices are also disclosed.

### FIELD

The present disclosure relates to semiconductor devices. In particular, the disclosure relates to semiconductor devices having mesa structures.

### BACKGROUND

Many semiconductor devices, including junction field effect transistors (JFETs), metal-oxide-semiconductor field effect transistors (MOSFETs), and others, have mesa structures including a plurality of mesa stripes in the active region of the device. Mesa structures can be used to provide device isolation, while stripe structures can help to distribute operating current evenly over the area of the device.

### SUMMARY

A method of forming a semiconductor device includes forming mesa stripe structure on a semiconductor substrate, the mesa stripe structure including a plurality of alternating trenches and mesa stripes, forming a dielectric spacer on the mesa stripe structure, and forming an etch mask on a portion of the mesa stripe structure. The etch mask covers at least a portion of a first mesa stripe of the plurality of mesa stripes. The dielectric spacer is etched to expose surfaces of the mesa stripes other than the portion of the first mesa stripe that is covered by the etch mask. The etch mask is removed, and a metal layer is formed on the mesa stripe structure. The metal layer forms metal contacts to the exposed surfaces of the mesa stripes.

The etch mask may cover a side surface of the first mesa stripe that is oblique to an upper surface of the semiconductor substrate.

The side surface of the first mesa stripe may include an end side surface of the first mesa stripe. The first mesa stripe may include an outermost mesa stripe of the plurality of mesa stripes.

The side surface of the first mesa stripe may include an outer sidewall the first mesa stripe that faces away from the mesa stripe structure.

The etch mask may be formed on an outer periphery of the mesa stripe structure and may cover end side surfaces of the plurality of mesa stripes and outer sidewalls of outermost ones of the plurality of mesa stripes.

The semiconductor device may be a junction field effect device or a metal oxide semiconductor field effect device.

The etch mask may expose a portion of the semiconductor substrate outside the mesa stripe structure.

The etch mask may cover at least one trench of the plurality of trenches.

The etch mask may at least partially cover at least one mesa stripe adjacent the first mesa stripe.

At least portions of the dielectric spacer may remain on the portion of the first mesa stripe that is covered by the etch mask after forming the metal contacts to the exposed surfaces of the mesa stripes.

Etching the dielectric spacer may include anisotropically etching the dielectric spacer to expose upper surfaces of the mesa stripes and bottom surfaces of the trenches.

Anisotropically etching the dielectric spacer may include performing a reactive ion etch.

The first mesa stripe may include an outermost one of the mesa stripes.

Etching the dielectric spacer may expose bottom surfaces of the trenches in regions of the mesa stripe structure that are exposed by the etch mask.

The first mesa stripe may have opposing sidewalls that are asymmetric.

The metal layer may simultaneously forms metal contacts on the mesa stripes and on bottom surfaces of the trenches.

A semiconductor structure according to some embodiments includes a semiconductor substrate, and a mesa stripe structure on the semiconductor substrate. The mesa stripe structure includes a plurality of alternating trenches and mesa stripes. The structure includes a plurality of first contacts on upper surfaces of a plurality of mesa stripes of the mesa stripe structure other than a first mesa stripe of the mesa stripe structure. Upper surfaces of the first mesa stripe are free of the first contacts.

The first mesa stripe may include an outermost one of the mesa stripes.

The first contacts may be formed on central portions of the mesa stripes other than the first mesa stripe, and end portions of the mesa stripes may be free of the first contacts.

The semiconductor structure may further include a spacer layer on an upper surface of the first mesa stripes. Mesa stripes other than the first mesa stripe may be free of the spacer layer.

The semiconductor structure may further include second contacts on bottom surfaces of the trenches. The first contacts and the second contacts may be formed from a single metal layer.

A semiconductor structure according to some embodiments includes a semiconductor substrate and a mesa stripe structure on the semiconductor substrate. The mesa stripe structure includes a plurality of alternating trenches and mesa stripes. At least one mesa stripe of the mesa stripe structure is covered by a dielectric layer. In some embodiments, the least one mesa stripe structure is entirely covered by the dielectric layer.

The semiconductor structure may further include a plurality of contacts on upper surfaces of a plurality of the mesa stripes of the mesa stripe structure other than the at least one mesa stripe of the mesa stripe structure. Upper surfaces of the first mesa stripe may be free of the contacts.

In some embodiments, the at least one mesa stripe is an outermost one of the mesa stripes.

The contacts may be formed on central portions of the mesa stripes other than the at least one mesa stripe, and end portions of the mesa stripes may be free of the contacts.

The semiconductor structure may further include a spacer layer on an upper surface of the at least one mesa stripe. Mesa stripes other than the at least one mesa stripe may be free of the spacer layer.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a plan view of a semiconductor device structure.

FIGS. 2A, 2B, 2C, 2D and 2E illustrate operations of forming semiconductor device structures.

FIG. 3 is a plan view of a semiconductor device structure according to some embodiments.

FIGS. 4A, 4B, 4C and 4D illustrate operations of forming device structures according to some embodiments.

FIG. 5 is a flowchart that illustrates operations for fabricating a semiconductor device structure according to some embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

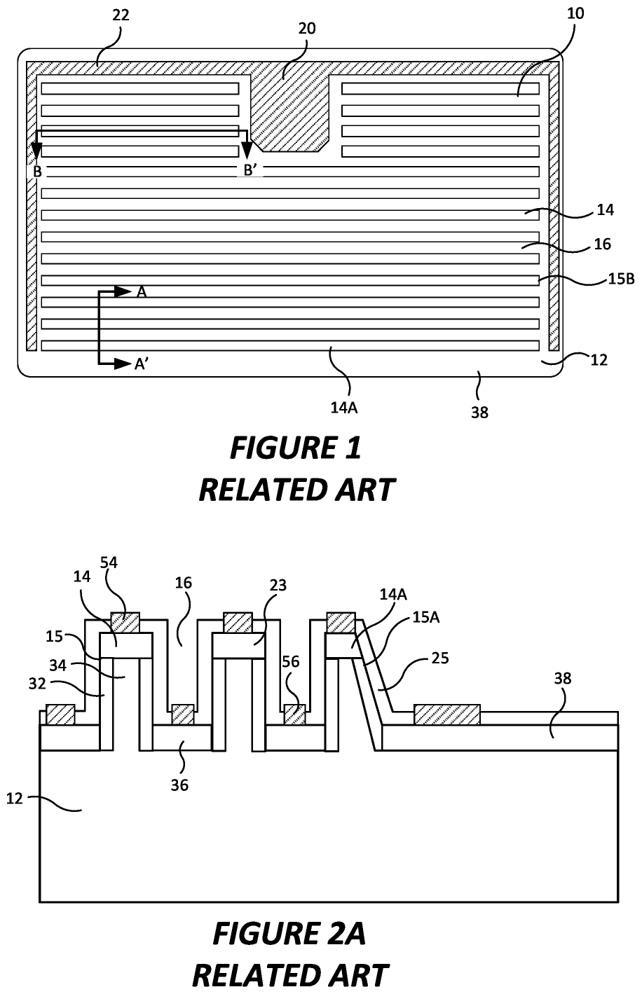

FIG. 1 illustrates, in plan view, a JFET semiconductor device 10 that includes a plurality of alternating mesa stripes 14 and trenches 16 formed in a semiconductor epitaxial layer on the surface of a substrate 12. The substrate 12 and epitaxial layers comprising the active region of the device 10 may include a semiconductor material, such as silicon, silicon carbide, or other silicon-containing semiconductor compound.

The plurality of alternating mesa stripes 14 and trenches 16 define an active region of the device 10. The device 10 includes a metal contact, which may, for example, include a gate pad 20 and gate runner 22 that provide electrical connection to gate contacts of the device 10. An area of the substrate 12 outside the active region (e.g., outside outermost mesa stripes 14A of the plurality of mesa stripes 14) defines a field region 38 of the device.

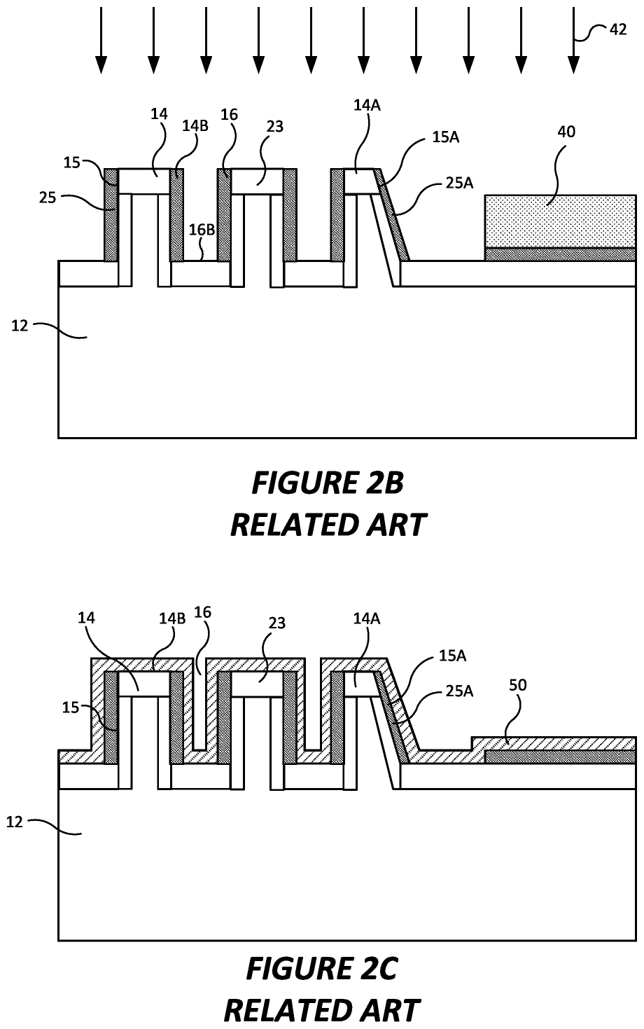

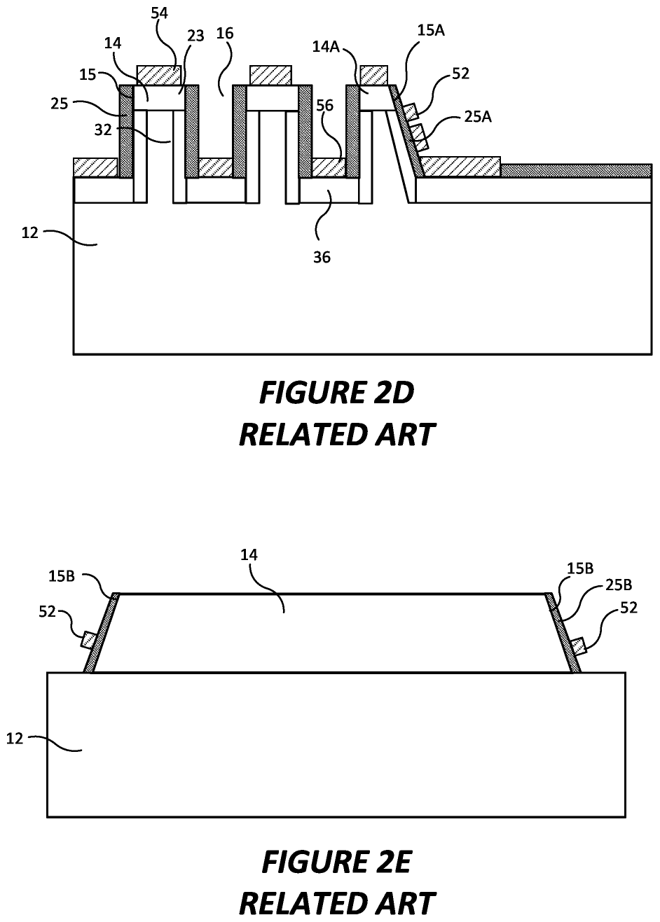

FIG. 2A is a cross-sectional view of the semiconductor device 10 taken along line A-A′ of FIG. 1. The device 10 includes a plurality of alternating mesa stripes 14 and trenches 16 arranged in a stripe pattern on the substrate 12. The device 10 includes various doped regions that define the operation of the device 10, including a source region 23 in a top portion of each mesa stripe 14, a JFET channel region 34 below the source region 23, and gate regions 32 in opposite sidewall regions of the mesa stripe 14. Gate contact regions 36 are formed at the bottoms of the trenches 16. The doped regions, such as the gate regions 32, gate contact regions 36 and source regions 23, may be doped with appropriate dopant types and/or concentrations. For example, the gate regions 32 and gate contact regions 36 may be doped with first conductivity type dopants (e.g., p-type dopants), while the source regions 23, channel regions 34 and substrate 12 may be doped with second conductivity type dopants (e.g., n-type dopants), or vice-versa. Doping may be performed in-situ during growth of the respective regions or subsequently using ion implantation.

Each mesa stripe 14 has opposing sidewalls 15, which are generally vertical (i.e., perpendicular) relative to the upper surface of the substrate 12. As shown in FIG. 2A, an outermost sidewall 15A of the outermost mesa stripe 14A of the plurality of mesa stripes 14 may not be perpendicular relative to the substrate, but rather may be slanted or oblique relative to the upper surface of the substrate 12, causing the opposing sidewalls of the outermost mesa stripe 14A to be asymmetric. This phenomenon may occur during an etch process to form the mesa stripes 14 and trenches 16. Similarly, end side surfaces 15B of the mesa stripes 14 may be slanted or oblique relative to the surface of the substrate 12 rather than perpendicular to the surface of the substrate 12.

A dielectric spacer layer 25 is formed over the structure. Source contacts 54 and gate contacts 56 are formed on the device 10 and contact respective source contact regions 23 and gate contact regions 36 through the dielectric spacer layer 25.

FIGS. 2B through 2D are cross-sectional views of the semiconductor device 10 illustrating operations of forming the semiconductor device 10. Referring to FIG. 2B, after formation of the mesa stripes 14 and trenches 16 (and the doped regions therein), the dielectric spacer layer 25 is formed on the structure. The dielectric spacer 25 may include, for example, a material such as silicon nitride or silicon oxide. An etch mask 40 is formed on the field region 38 of the structure, and the exposed portions of the dielectric spacer 25 are etched using an anisotropic etch process 42, such as a reactive ion etch, to remove the dielectric spacer 25 from upper surfaces 14B of the mesa stripes 14 and bottom surfaces 16B of the trenches 16. As can be seen in FIG. 2B, because the etch process 42 is anisotropic and the mesa sidewalls 15 are generally vertical, the dielectric spacer 25 may not be removed from the sidewalls 15 of the mesa stripes 14 by the etch process. However, because the outermost sidewall 15A of the outermost mesa stripe 14 of the plurality of mesas is slanted or oblique relative to the surface of the substrate 12, the portion 25A of the dielectric spacer layer 25 on the outermost sidewall 15A may become thinner relative to other portions of the dielectric spacer layer 25 as a result of the anisotropic etch process 42.

Referring to FIG. 2C, after etching the dielectric spacer layer 25, the etch mask 40 is removed, and a metal layer 50, such as nickel, is blanket deposited on the structure to form the source and drain contacts. In particular, the metal layer 50 contacts the upper surfaces 14B of the mesa stripes 14 and the bottom surfaces 16B of the trenches 16 that were exposed by the etch process. The structure is then annealed in a silicidization anneal to cause portions of the metal layer 50 in contact with the silicon-containing semiconductor material to form metal silicide on the upper surfaces 14B of the mesa stripes 14 and the bottom surfaces 16B of the trenches 16.

Referring to FIG. 2D, after the silicidization anneal, the un-silicided portions of the metal layer 50 are stripped, leaving the metal silicide source contacts 54 and gate contacts 56 on the mesa stripes 14 and trenches 16, respectively. However, as seen in FIG. 2D, due to the thinning of the dielectric spacer 25 on the outermost sidewall 15A of the outermost mesa stripe 14A, the metal layer 50 may undesirably penetrate the dielectric spacer 25 in that area and form spurious metal silicide contacts 52 on the outermost sidewall 15A of the outermost mesa stripe 14A. These spurious contacts 52 may undesirably create conductive pathways, such as between the source contact region 23 and the gate regions 32, which may render the device 10 inoperable.

FIG. 2E is a cross section of the device 10 taken along line B-B′ of FIG. 1. As shown in FIG. 2E, end side surfaces 15B of the mesa stripes 14 may also be slanted or oblique and not perpendicular relative to the surface of the substrate 12, and thus spurious contacts 52 may also form on the end side surfaces 15B of the mesa stripes 14 due to thinning of the portions 25B of the dielectric spacer layer 25 on the end side surfaces 15B of the mesa stripes 14.

According to some embodiments, the formation of spurious metal contacts on oblique side surfaces of one or more mesa stripes of a mesa stripe structure may be reduced or avoided by protecting such oblique side surfaces during formation of metal contacts to the device so that metal contacts are not formed on the oblique side surfaces of the mesa stripes.

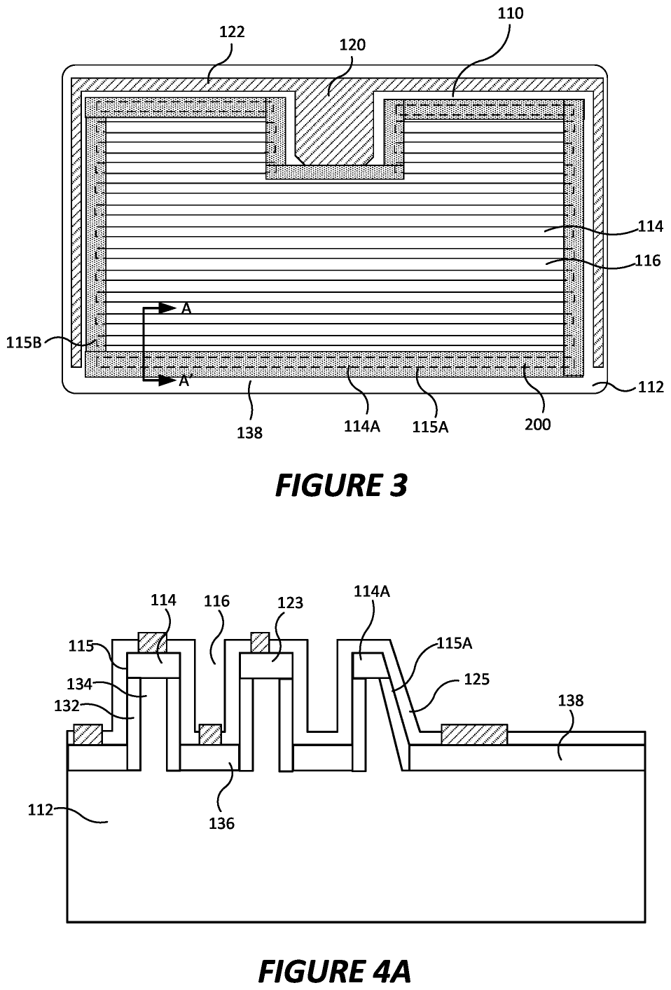

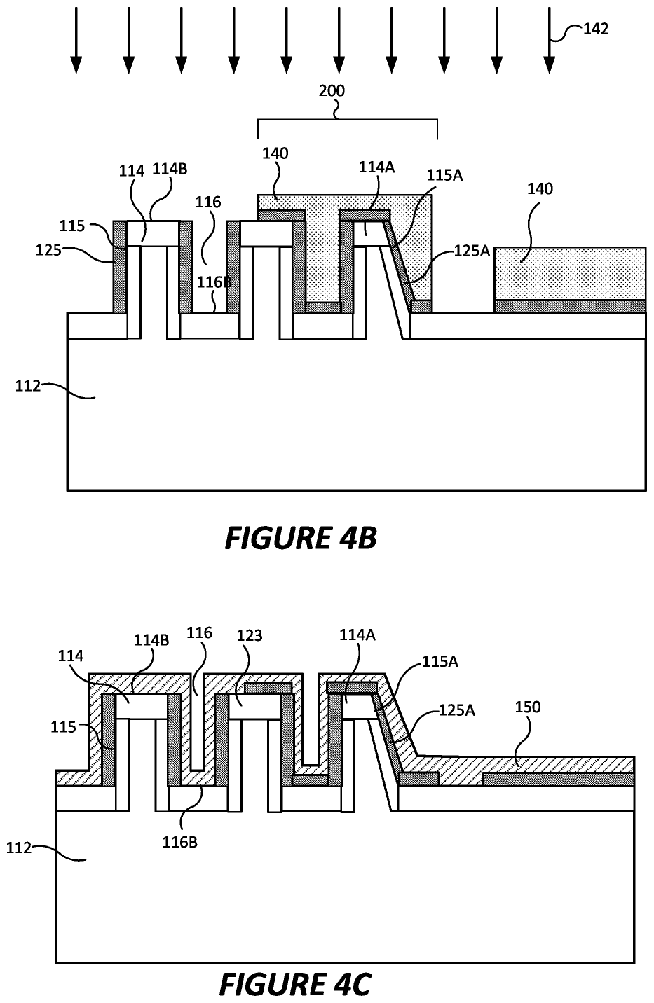

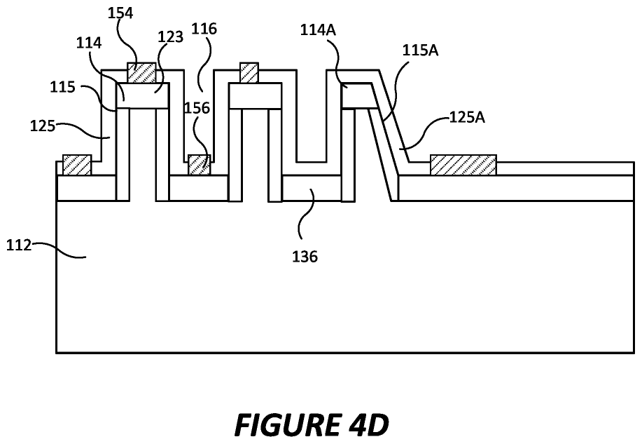

For example, FIG. 3 illustrates, in plan view, a JFET semiconductor device 110 according to some embodiments, and FIG. 4A is a cross-sectional view of the semiconductor device 110 taken along line B-B′ of FIG. 3. Referring to FIGS. 3 and 4A, the semiconductor device 100 has a plurality of alternating mesa stripes 114 and trenches 116 formed on the surface of a substrate 112 that define an active region of the device 110. The substrate 112 and epitaxial layers comprising the active region of the device 110 may include a semiconductor material, such as silicon, silicon carbide, or other silicon-containing semiconductor compound.

The device 110 includes a metal contact 120, 122, which may, for example, be a gate pad 120 and gate runner 122 that provide electrical connection to the gate contact of the device 110. An area of the substrate 112 outside the active region (e.g., outside outermost mesa stripe 114A of the plurality of mesa stripes 114) defines a field region 138 of the device.

As shown in FIG. 3, the device 110 has a cut-out region 200 that covers at least portions of outermost mesa stripes 114A of the plurality of mesa stripes 114 as well as end side surfaces 115B of the plurality of mesa stripes 114. No metallization is formed in the cut-out region 200. Thus, in contrast to conventional device structures, no metallization is formed on at least outer sidewalls 115A of the outermost mesa stripes 114A that could adversely affect the operation of the device 110. Additionally, no metallization is formed on the end side surfaces 115B of the mesa stripes 114 that could adversely affect the operation of the device 110.

Referring to FIG. 4A, the device 110 includes various doped regions that define the operation of the device 110, including a source region 123 in a top portion of each mesa stripe 114, a JFET channel region 134 below the source region 123, and p-type gate regions 132 in opposite sidewall regions of the mesa stripe 114. Gate contact regions 136 are formed at the bottoms of the trenches 116. Each mesa stripe 114 has opposing sidewalls 115, which are generally vertical relative to the upper surface of the substrate 112. The doped regions may be doped with appropriate dopant types and/or concentrations. For example, the gate regions 132 and gate contact regions 136 may be doped with first conductivity type dopants (e.g., p-type dopants), while the source regions 123, channel regions 134 and substrate 112 may be doped with second conductivity type dopants (e.g., n-type dopants), or vice-versa. Doping may be performed in-situ during growth of the respective regions or subsequently using ion implantation.

As shown in FIG. 4A, an outermost side wall 115A of the outermost mesa stripe 114A may not be vertical, but rather may be slanted or oblique relative to the upper surface of the substrate 112. A dielectric spacer layer 125 is formed over the structure. Source contacts 154 and gate contacts 156 are formed on the device 110 and contact respective source contact regions 123 and gate contact regions 136 through the dielectric spacer layer 125.

FIGS. 4B through 4D are cross-sectional views of the semiconductor device 110 illustrating operations of forming the semiconductor device 110. Referring to FIG. 4B, after formation of the mesa stripes 114 and trenches 116 (and the doped regions therein), the dielectric spacer layer 125 is formed on the structure. The dielectric spacer 125 may include a material such as silicon nitride or silicon oxide. An etch mask 140 is formed on the field region 138 of the structure as well as over the substrate in the cut-out region 200.

The exposed portions of the dielectric spacer 125 are etched using an anisotropic etch process 142, such as a reactive ion etch, to remove the dielectric spacer 125 from upper surfaces 114B of the mesa stripes 114 and bottom surfaces 116B of the trenches 116. As can be seen in FIG. 4B, due to the presence of the etch mask 40 in the cut-out region 200, the portions of the dielectric spacer 125 over the at least the outermost surfaces 115A of the outermost mesa stripes 114A are not removed by the etch process 142.

Referring to FIG. 4C, after etching the dielectric spacer layer 125, the etch mask 140 is removed, and a metal layer 150, such as nickel, is blanket deposited on the structure to form the source and drain contacts. In particular, the metal layer 150 contacts the upper surfaces 114B of the mesa stripes 114 and the bottom surfaces 116B of the trenches 116 that were exposed by the etch process. However, no part of the metal layer 150 contacts upper surfaces 114B of the mesa stripes 114 and the bottom surfaces 116B of the trenches 116 that were covered by the etch mask 140 within the cut-out region 200. The structure is then annealed to form metal silicide regions on the upper surfaces 114B of the mesa stripes 114 and the bottom surfaces 116B of the trenches 116 other than the portions within the cut-out region 200.

Referring to FIG. 4D, after the silicidization anneal, the un-silicided portions of the metal layer 150 are stripped, leaving the metal silicide source contacts 154 and gate contacts 156 on the mesa stripes 114 and trenches 116, respectively, other than within the cut-out region 200. Accordingly, unwanted metal silicide contacts may not be formed on outer sidewalls 115A of the outermost mesa stripes 114A or end side surfaces 115B of the plurality of mesa stripes 114. Additionally, metal silicide source contacts 154 may not be formed on at least some of the plurality of mesa stripes 114 and gate contacts 156 may not be formed on at least some of the trenches 116.

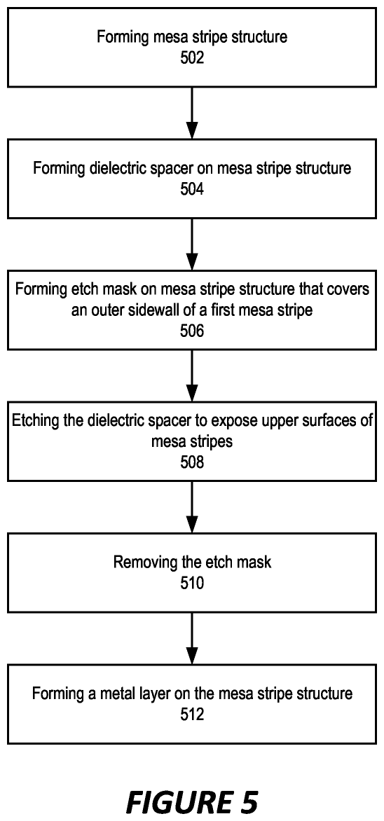

FIG. 5 is a flowchart that illustrates operations of forming a semiconductor device 110 according to some embodiments. The semiconductor device 110 may, for example, be a junction field effect device or a metal oxide semiconductor field effect device.

Referring to FIGS. 4A-4D and FIG. 5, the operations include forming mesa stripe structure on a semiconductor substrate. The mesa stripe structure includes a plurality of alternating trenches 116 and mesa stripes 114 (block 502). A dielectric spacer 125 is formed on the mesa stripe structure (block 504), and an etch mask 140 is formed on the mesa stripe structure (block 506).

The etch mask 140 covers at least an outer sidewall 115A of a first mesa stripe 114A of the plurality of mesa stripes 114. For example, the etch mask 140 may cover at least an outer surface 115A of an outermost mesa stripe 114A of the plurality of mesa stripes 114. The etch mask 140 may also cover an end portion 115B of at least one of the mesa stripes 114. The etch mask 140 may be formed on an outer periphery of the mesa stripe structure, and defines a cut-out area 200 of the semiconductor device structure. The etch mask 140 may at least partially cover a mesa stripe 114 other than the first mesa stripe 114A. In some embodiments, the etch mask 140 may surround the mesa stripe structure. The etch mask 140 may expose a portion of the semiconductor substrate 112 outside the mesa stripe structure. In some embodiment, the etch mask 140 may cover at least one trench 116 of the plurality of trenches 116. In some embodiments, the etch mask 140 may at least partially cover at least one mesa stripe 114 other than the first mesa stripe 114A.

The method further includes etching the dielectric spacer 125 to expose surfaces of the mesa stripes 114, other than the first mesa stripe 114A, in regions of the mesa stripe structure that are exposed by the etch mask 140 (block 508).

The etch mask 140 is then removed (block 510), and a metal layer 150 is formed on the mesa stripe structure (block 512). The metal layer 150 forms metal contacts 154, 156 to the exposed surfaces of the mesa stripes 114. Following the etch process, portions of the dielectric spacer 140 may remain on the outer sidewall of the one of the mesa stripes 114 after formation of the metal contacts 155, 156 to the upper surfaces 114A of the mesa stripes 114 and bottom surfaces 116B of the trenches 116.

In some embodiments, etching the dielectric spacer 125 includes anistotripically etching the dielectric spacer 125 to expose upper surfaces 114B of the mesa stripes 114 and bottom surfaces 116B of the trenches 116 while leaving portions of the dielectric spacer 125 on sidewalls 115 of the mesa stripes 114. The etch process may include a reactive ion etch process. Etching the dielectric spacer 125 may expose bottom surfaces 116B of the trenches 116 in regions of the mesa stripe structure that are exposed by the etch mask 140.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although embodiments of the inventive concepts have been described in considerable detail with reference to certain configurations thereof, other versions are possible. Accordingly, the spirit and scope of the invention should not be limited to the specific embodiments described above.

1. A method of forming a semiconductor device, comprising:
forming mesa stripe structure on a semiconductor substrate, the mesa stripe structure comprising a plurality of alternating trenches and mesa stripes;
forming a dielectric spacer on the mesa stripe structure;
forming an etch mask on a portion of the mesa stripe structure, wherein the etch mask covers at least a portion of a first mesa stripe of the plurality of mesa stripes;
etching the dielectric spacer to expose surfaces of the mesa stripes other than the portion of the first mesa stripe that is covered by the etch mask;
removing the etch mask; and
forming a metal layer on the mesa stripe structure, wherein the metal layer forms metal contacts to the exposed surfaces of the mesa stripes.

2. The method of claim 1, wherein the etch mask covers a side surface of the first mesa stripe that is oblique to an upper surface of the semiconductor substrate.

3. The method of claim 2 wherein the side surface of the first mesa stripe comprises an end side surface of the first mesa stripe.

4. The method of claim 2, wherein the first mesa stripe comprises an outermost mesa stripe of the plurality of mesa stripes.

5. The method of claim 4, wherein the side surface of the first mesa stripe comprises an outer sidewall the first mesa stripe that faces away from the mesa stripe structure.

6. The method of claim 1, wherein the etch mask is formed on an outer periphery of the mesa stripe structure and covers end side surfaces of the plurality of mesa stripes and outer sidewalls of outermost ones of the plurality of mesa stripes.

7. The method of claim 1, wherein the semiconductor device comprises a junction field effect device or a metal oxide semiconductor field effect device.

8. The method of claim 1, wherein the etch mask exposes a portion of the semiconductor substrate outside the mesa stripe structure.

9. The method of claim 1, wherein the etch mask covers at least one trench of the plurality of trenches.

10. The method of claim 1, wherein the etch mask at least partially covers at least one mesa stripe adjacent the first mesa stripe.

11. The method of claim 1, wherein the dielectric spacer remains on the portion of the first mesa stripe that is covered by the etch mask after forming the metal contacts to the exposed surfaces of the mesa stripes.

12. The method of claim 1, wherein etching the dielectric spacer comprises anisotropically etching the dielectric spacer to expose upper surfaces of the mesa stripes and bottom surfaces of the trenches.

13. The method of claim 12, wherein anisotropically etching the dielectric spacer comprises performing a reactive ion etch.

14. The method of claim 1, wherein the first mesa stripe comprises an outermost one of the mesa stripes.

15. The method of claim 1, wherein etching the dielectric spacer exposes bottom surfaces of the trenches in regions of the mesa stripe structure that are exposed by the etch mask.

16. The method of claim 1, wherein the first mesa stripe comprises opposing sidewalls that are asymmetric.

17. The method of claim 1, wherein the metal layer simultaneously forms metal contacts on the mesa stripes and on bottom surfaces of the trenches.

18. A semiconductor structure, comprising:
a semiconductor substrate;
a mesa stripe structure on the semiconductor substrate, wherein the mesa stripe structure comprises a plurality of alternating trenches and mesa stripes; and
a plurality of first contacts on upper surfaces of a plurality of mesa stripes of the mesa stripe structure other than a first mesa stripe of the mesa stripe structure;
wherein upper surfaces of the first mesa stripe are free of the first contacts.

19. The semiconductor structure of claim 17, wherein the first mesa stripe comprises an outermost one of the mesa stripes.

20. The semiconductor structure of claim 17, wherein the first contacts are formed on central portions of the mesa stripes other than the first mesa stripe, and wherein end portions of the mesa stripes are free of the first contacts.

21. The semiconductor structure of claim 17, further comprising:
a spacer layer on an upper surface of the first mesa stripe, wherein mesa stripes other than the first mesa stripe are free of the spacer layer.

22. The semiconductor structure of claim 17, further comprising second contacts on bottom surfaces of the trenches.

23. The semiconductor structure of claim 22, wherein the first contacts and the second contacts are formed from a single metal layer.

24. A semiconductor structure, comprising:
a semiconductor substrate; and
a mesa stripe structure on the semiconductor substrate, wherein the mesa stripe structure comprises a plurality of alternating trenches and mesa stripes;
wherein at least one mesa stripe of the mesa stripe structure is covered by a dielectric layer.

25. The semiconductor structure of claim 24, further comprising:
a plurality of contacts on upper surfaces of a plurality of the mesa stripes of the mesa stripe structure other than the at least one mesa stripe of the mesa stripe structure;
wherein upper surfaces of the first mesa stripe are free of the contacts.

26. The semiconductor structure of claim 24, wherein the at least one mesa stripe comprises an outermost one of the mesa stripes.

27. The semiconductor structure of claim 24, wherein the contacts are formed on central portions of the mesa stripes other than the at least one mesa stripe, and wherein end portions of the mesa stripes are free of the contacts.

28. The semiconductor structure of claim 24, further comprising:
a spacer layer on an upper surface of the at least one mesa stripe, wherein mesa stripes other than the at least one mesa stripe are free of the spacer layer.

29. The semiconductor structure of claim 24, further comprising second contacts on bottom surfaces of the trenches.

30. The semiconductor structure of claim 29, wherein the first contacts and the second contacts are formed from a single metal layer.

31. The semiconductor structure of claim 24, wherein the at least one mesa stripe is entirely covered by a dielectric layer.
